(19) United States
(12) Patent Application Publication
(10) Pub. No.: US 2005/0269713 A1
(43) Pub. Date: Dec. 8, 2005

(54) Apparatus and method for wire bonding and die attaching

(76) Inventors: Kook-Jin Oh, Cheonan-si (KR); Dae-Soo Kim, Cheonan-si (KR); Dong-Bin Kim, Cheonan-si (KR); Suk-Chun Jung, Cheonan-si (KR); Sang-Woo Lee, Cheonan-si (KR); Byung-Soo Kim, Cheonan-si (KR)

Correspondence Address: HARNESS, DICKEY & PIERCE, P.L.C., P.O. BOX 8910, RESTON, VA, 20195, US

(21) Appl. No.: 11/047,569

(22) Filed: Feb. 2, 2005

(30) Foreign Application Priority Data
Jun. 5, 2004 (KR) 2004-41188

(51) Int. Cl. H01L 23/48; H01L 21/48

(52) U.S. Cl. 257/777; 438/109

(57) ABSTRACT

An apparatus and method for wire bonding and die attaching using a system for determining reject frames by determining a z-level distance using a z-axis sensor are provided. The apparatus includes a z-axis sensor that may be moved between a reference position and an upper surface of frames on a PCB; a z-axis sensor controller for positioning and moving the z-axis sensor relative to the frame to measure the z-level distance between the reference position and a z-axis sensor contact position on an upper surface of the frame; and a host controller for determining whether the frame is a reject frame by comparing the measured z-level distance with a reference level. The apparatus and method provides for the dynamic determination of which frames are suitable for additional processing with a low error rate and thereby increase the exclusion rate for reject frames resulting in increased production capacity.

### BACKGROUND OF THE INVENTION

This application claims the priority of Korean Patent Application No. 2004-41188, filed on Jun. 5, 2004, in the Korean Intellectual Property Office, the disclosure of which is incorporated herein in its entirety by reference.

1. Field of the Invention

The present invention relates to an apparatus and method for packaging a semiconductor chip, and more particularly, to an apparatus and method for wire bonding and die attaching operations.

2. Description of the Related Art

Semiconductor chips must be packaged for protection. This may be done by attaching each semiconductor chip to a frame, connecting wires between pads on the chip and corresponding conductors on the frame, and sealing the frame, chip and bonding wires in a molding compound. Recently, PCBs (Printed Circuit Boards) having many frames have been used to reduce package manufacturing time. Also, stack-type packages have been developed for increasing package integration by allowing several semiconductor chips to be arranged in a vertical configuration on a single frame of the PCB. Such advances have made chip packaging even more complicated and time consuming, especially at the wire bonding stage.

The process of bonding wires to the semiconductor chip connects electrode pads on the chip to leads on the PCB using a conductive bonding wire, usually including gold or aluminum, to provide for connection to external devices. Errors caused by semiconductor chips missing from frames have been a considerable problem in reducing the processing time for wire bonding using the PCBs. The conventional apparatus and method for wire bonding will now be described with reference to the accompanying drawings.

FIGS. 1A through ID are drawings illustrating a conventional apparatus and method for wire bonding. As illustrated in FIG. 1A, a PCB 100 having a plurality of frames is prepared with frames 105, 110, 115, 120, 130, 135, 140, 145, 155, and 160, on which corresponding semiconductor chips 107, 112, 117, 122, 132, 137, 142, 147, 157 and 162 are attached, (referred to as package frames hereinafter). Also illustrated in FIG. 1A are reject frames 125 and 150 on which no semiconductor chips have been attached. Generally, most of the reject frames are not used due to errors during the manufacture of the PCB. However, in some rare cases, such reject frames may be generated because no semiconductor chip is attached to the frame of the PCB, or because the semiconductor chip has separated from the frame after an initial attachment.

FIG. 1B illustrates an enlarged part 105a of region B of a first package frame 105 from FIG. 1A and shows a portion of the frame pattern 106a provided on the frame and a semiconductor chip 107a attached over central portion of the frame pattern. The region on which the semiconductor chip 107a is attached is called a chip-mounting region. FIG. 1C illustrates an enlarged part 125a of a first reject frame 125 from FIG. 1A shows a reject mark 128a that has been formed within the chip-mounting region 127a of frame pattern 126a. The reject mark 128a indicates that the frame 125 is a reject frame.

As illustrated in FIG. 1D, according to the conventional method for wire bonding, the PCB is first recognized and aligned 180. Subsequently, a semiconductor chip on one frame of the PCB is recognized and aligned 182. If the semiconductor chip is recognized, a wire-bonding operation is performed 186. However, if the semiconductor chip is not recognized 182 and the reject mark is recognized 184, the frame will be designated as a reject frame and the wire bonding process will be omitted for that frame 188. However, if neither the semiconductor chip 182 nor the reject mark 184 are recognized, an error message is output and the process is stopped 190.

If the process is stopped in this manner 190, an operator checks, in person, whether or not a semiconductor chip appears to be properly attached to the frame. If, during this check, the operator determines that no semiconductor chip is attached, the operator will make a suitable reject mark on the frame. If, however, the operator determines that a semiconductor chip is properly attached to the frame, the operator will restart the series of operations for the inspected frame. After the wire bonding is performed 186 or omitted 188, the process moves to the next frame 192 and the above process is repeated.

According to the conventional method, the equipment is stopped whenever a reject frame is received without a reject mark, typically resulting from an error by the PCB manufacturing company or an error during the process. Also, there is possibility that errors may occur if the reject marks, although present, are not consistently recognized by the camera. Further, in stack-type semiconductor chip products, a mistakenly mounted semiconductor chip will tend to obscure the portion of the frame or lower semiconductor chip that would include the reject mark, resulting in the wire bonding of defective products.

Another conventional method utilizes a camera to detect and recognize the semiconductor chip or chips that will be included in the chip stack product. This method relies on pattern recognition for determining whether the expected semiconductor chip is present on the frame. The expected patterns may be obtained by photographing or otherwise collecting image data regarding the specific pattern for each semiconductor chip that will be used in each of the products to be processed by the apparatus. Accordingly, if the pattern recognition process determines that the appropriate chip pattern is found on the examined frame, the frame is determined to be a package frame suitable for additional processing and, if no chip pattern is recognized, the frame is determined to be a reject frame. However, this method is limited because the step difference and the optical contrast in the semiconductor chip pattern are not uniform, there remains a possibility that the pattern recognition will fail and because it requires that sufficient semiconductor chip pattern recognition information must be stored or readily accessible for every chip that may pass through the apparatus.

According to another conventional method, as shown in FIG. 1E, a reject frame map 195 may be provided along a peripheral portion, in this instance along the left of PCB 100a, for indicating which frames are rejects. As illustrated in FIG. 1E, The open or unmarked frame indicators 195a correspond to good or passing frames while the closed or marked frame indicators 195b correspond to failing or reject frames in frame map 195. The method of using the reject frame map can reduce recognition error compared to the method of attempting to locate and recognize a reject mark within the failing frame. However, there still remains the possibility that errors may be generated by the apparatus. For example, if the frame map is not updated during processing, it will indicate only the initially rejected frames and will not serve to prevent additional processing of frame locations that have incurred some subsequent processing problem during the production of the stack-type semiconductor chip package. Conversely, if the reject frame map is not accurate or is not read accurately, there is a possibility that the apparatus may confuse good frames and reject frames, resulting the additional processing of reject frames and the failure to process good frames properly by omitting subsequent chip attaching and/or wire bonding processes.

### SUMMARY OF THE INVENTION

Exemplary embodiments of the present invention provide an apparatus for wire bonding and die attaching capable of increasing the rate of automatically omitting wire bonding and die attaching on reject frames, by determining, with a low error rate, reject frames on which no semiconductor chips or an insufficient number of semiconductor chips are attached.

Exemplary embodiments of the present invention also provide a method for wire bonding capable of reducing downtime of the apparatus by efficiently determining reject frames of a PCB (Printed Circuit Board) with respect to both frames on which a single semiconductor chip is to be attached and frames on which a plurality of stack-type chips are to be attached and by increasing the rate of automatically omitting wire bonding of reject frames during the process of packaging a semiconductor chip.

According to an aspect of the present invention, there is provided an apparatus for wire bonding and die attaching that includes a system for determining reject frames, the apparatus including: a z-axis sensor for moving up and down above the frames of a PCB having a plurality of package frames on which a single stack-type semiconductor chip or a plurality of stack-type semiconductor chips are attached, and a plurality of reject frames on which no semiconductor chips or an insufficient number of semiconductor chips are attached; a z-axis sensor controller for controlling the movement of the z-axis sensor and measuring a z-level distance between a reference position and the point where the z-axis sensor touches the upper surface of the frames (as used herein this includes the upper surface of a semiconductor chip or a stack of semiconductor chips mounted on the frame); and a host controller for determining whether the frames are reject frames on the basis of the measured z-level distance.

The z-axis sensor may be a capillary-type probe that is configured for contacting the upper surface of the frames to measure the z-level in a manner that does not tend to mark or damage the contacted portion of the surface by using, for example, a contact force of less than 30 grams force. Further, the z-axis sensor controller may read the change of a pulse current to compare it with a set sensitivity, or measures a load change applied to the z-axis sensor, to recognize the point when the z-axis sensor touches the upper end of the frames.

Also, the apparatus for wire bonding and die attaching may additionally include a camera and an alignment apparatus for recognizing and aligning the semiconductor chip. Further, the z-axis sensor controller may be engaged and operate only in those instances in which the camera does not recognize the semiconductor chip and/or a reject mark.

Further, the host controller may designate the probed frames as reject frames if the measured z-level distance is greater than a reference level corresponding to the anticipated thickness of the frame and/or any semiconductor chip(s) that should be attached to the frames. Further, the reference level may be inversely proportional to the anticipated thickness of the semiconductor chip or stack of semiconductor chips attached on the frames.

According to another aspect of the present invention, there is provided a method for wire bonding that includes: recognizing and aligning a PCB having a plurality of package frames on which a plurality of stack-type semiconductor chips are attached, and a plurality of reject frames, on which no semiconductor chips are attached; measuring a z-level distance between a reference position and the upper end of one frame; determining if the measured frame is a reject frame by comparing the z-level with a reference level; and, if the frame is determined to be a reject frame, omitting the wire-bonding operation and moving to the next frame, and if the frame is determined to be a package frame, performing the wire-bonding operation.

The operation during which the frame status is evaluated determines that the frame is a reject frame when the measured z-level is greater than a reference level corresponding to the surface of at least one semiconductor chip that will be attached to the frame in a properly assembled semiconductor product. Further, the reference level may be inversely proportional to the thickness of the semiconductor chip or stack of semiconductor chips attached on the frames.

Further, the operation of measuring the z-level may use the z-axis sensor and read a change in a pulse current and compare it with a set sensitivity in order to recognize the point where the z-axis sensor touches the upper surface of the frames. According to still another aspect of the present invention, there is provided a method for wire bonding that includes: recognizing and aligning a PCB having a plurality of package frames, on which a plurality of stack-type semiconductor chips are attached, and a plurality of reject frames, on which no semiconductor chips are attached; recognizing and aligning a semiconductor chip on one frame; if the semiconductor chip is recognized, performing a wire-bonding operation and if the semiconductor chip is not recognized, measuring a z-level distance between a reference position and the upper surface of the frame; determining whether the frame is a reject frame by comparing the z-level with a reference level; and, if the frame is determined to be a reject frame, omitting wire-bonding and moving to the next frame, and if the frame is determined to be a non-reject frame, outputting an error message to stop the process, log the error and/or notify an operator. The operation of recognizing the semiconductor chip typically uses a camera and a system having a pattern recognition function.

Also, the operation of measuring the z-level may include lowering the z-axis sensor toward the center of a semiconductor-chip-mounting region using a mechanism configured to produce a contact force of sufficiently small magnitude to avoid marking or damaging the contacted surface or underlying structures. In some instances, a z-axis sensor contact force of not more that about 20 to 30 grams force will be sufficient to achieve this goal of not damaging the upper surface of the frames. Also, the operation of determining whether the frame is a reject frame may allow for designating the frame as a reject frame if the z-level is greater than a reference level even if the upper surface of the frame has not been contacted. The reference level may be in inverse proportion to the thickness of the semiconductor chip or stack of semiconductor chips attached on the frames.

### BRIEF DESCRIPTION OF THE DRAWINGS

The present invention will become more apparent by describing in detail exemplary embodiments thereof with reference to the attached drawings in which:

FIGS. 1A through 1E are drawings showing an apparatus and method for wire bonding using a conventional system for determining reject frames;

FIGS. 2A through 2D are drawings showing an apparatus and method for wire bonding and die attaching using a system for determining reject frames according to one embodiment of the present invention;

FIGS. 3A through 3D are drawings showing a method for wire bonding using a system for determining reject frames according to another embodiment of the present invention; and

FIG. 4 is a drawing showing a method for wire bonding using a system for determining reject frames according to still another embodiment of the present invention.

### DETAILED DESCRIPTION OF EXEMPLARY EMBODIMENTS

The present invention will now be described more fully with reference to the accompanying drawings, in which exemplary embodiments of the invention are shown. As will be appreciated, however, the invention may be embodied in many different forms and should not be construed as being limited to the embodiments set forth herein. These disclosed embodiments are, however, are provided so that this disclosure will be thorough and complete, and will fully convey the concept of the invention to those skilled in the art.

### First Exemplary Embodiment

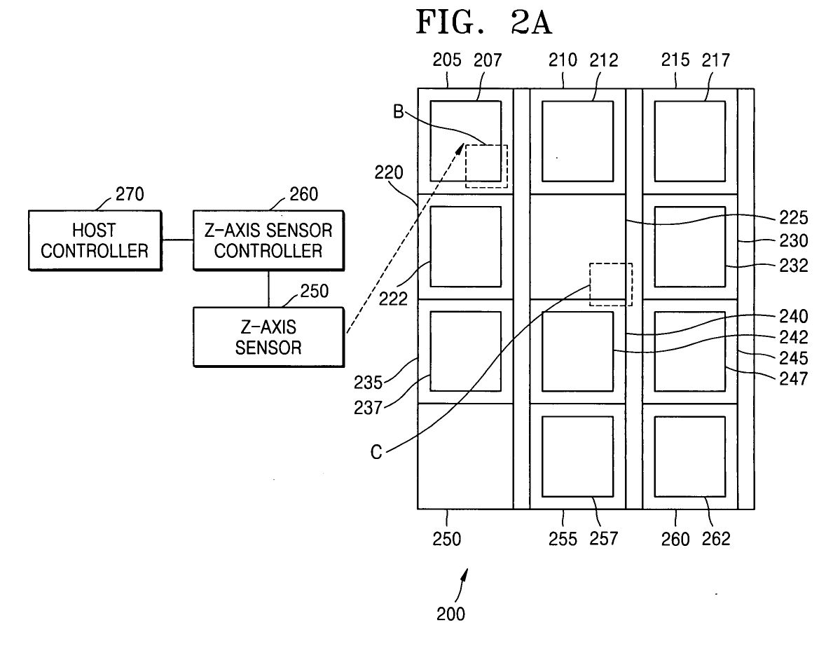

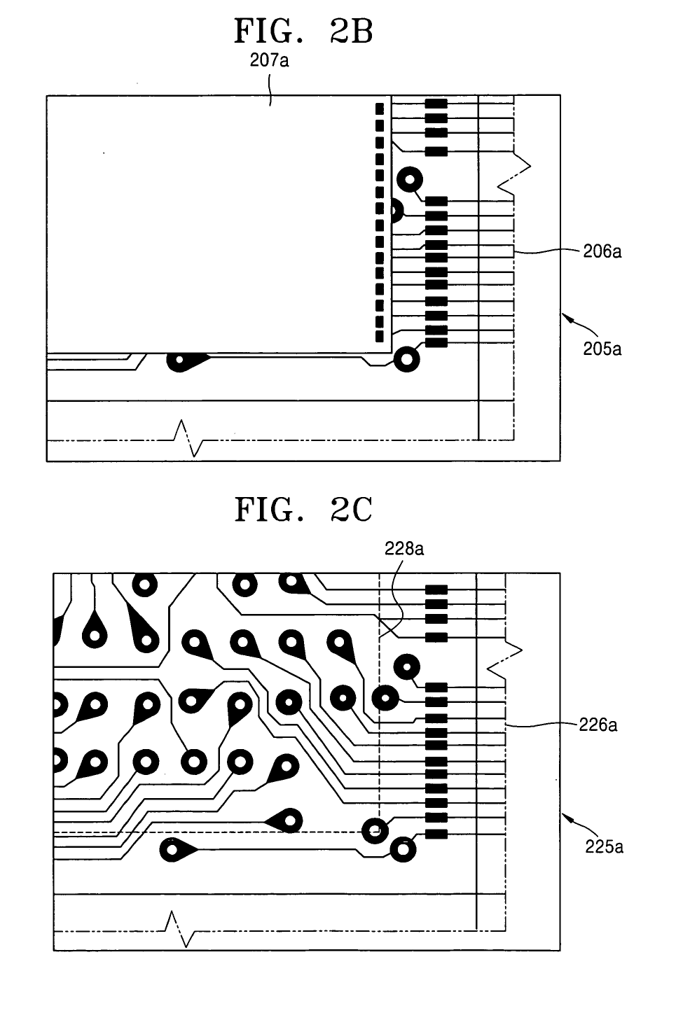

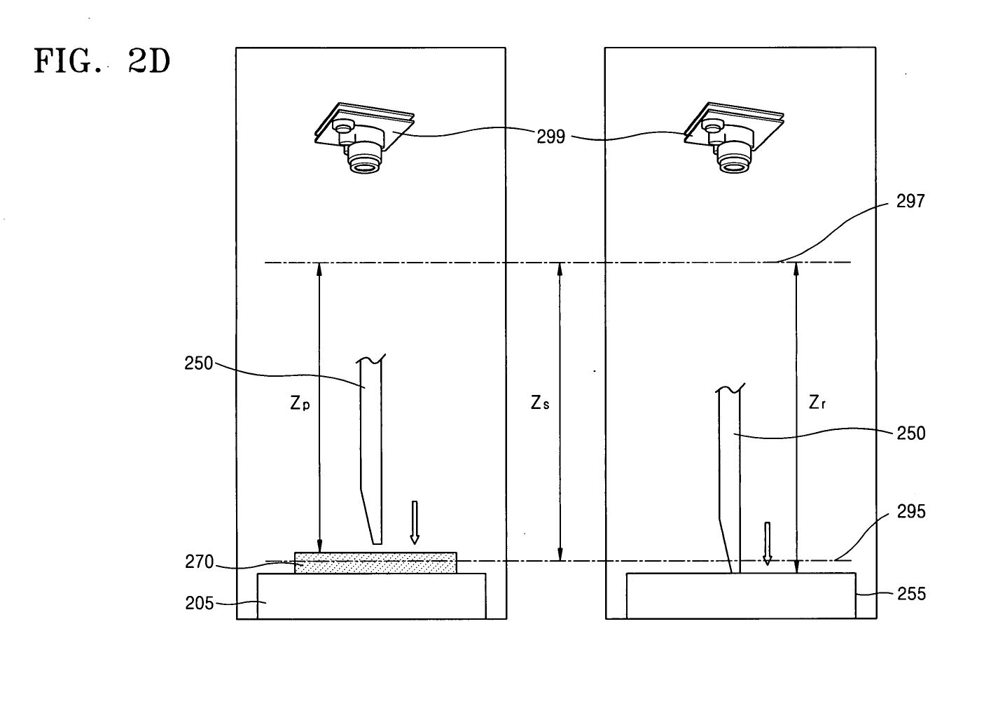

FIG. 2A is a block diagram showing a system for determining reject frames and a PCB in an apparatus for wire bonding and die attaching according to one embodiment of the present invention. FIG. 2B is an enlarged plan view of a general region B of package frame 205 of the PCB shown in FIG. 2A and FIG. 2C is an enlarged plan view of a general region C of reject package frame 225 of the PCB shown in FIG. 2A. FIG. 2D is a drawing showing a system for determining a reject frame using a z-level.

As illustrated in FIG. 2A, the system for determining reject frames in the apparatus for wire bonding and die attaching according to the present invention, includes: a z-axis sensor 250 for moving up and down on a PCB 200 having a plurality of frames; a z-axis sensor controller 260; and a host controller 270.

The PCB 200 includes package frames 205, 210, 215, 220, 230, 235, 240, 245, 255 and 260, on which one or more stack-type semiconductor chips 207, 212, 217, 222, 232, 237, 242, 247, 257 and 262 are respectively attached, and reject frames 225 and 250 on which no semiconductor chips are attached. It will be obvious to those skilled in the art that the number of package frames and reject frames may change depending on the PCB and are not limited to those shown in FIG. 2A.

As illustrated in FIG. 2B, a frame pattern 206a exists on an enlarged part 205a of the package frame 205, and a semiconductor chip 207a is attached to the frame pattern 206a. Other package frames of the PCB 200 may have the same basic structure as shown in the enlarged plan view of FIG. 2B. As illustrated in FIG. 2C, a frame pattern 226a exists on an enlarged part 225a of the reject frame 225, and no semiconductor chip is attached on a semiconductor-chip-mounting region 228a of the frame pattern 226a. Other reject frames of the PCB 200 may have the same basic structure as shown in the enlarged plan view of FIG. 2C.

As illustrated in FIG. 2D, a camera 299 and an alignment apparatus (not shown) may be additionally provided for the accurate positioning of both the package frame 205 on which a semiconductor chip 207 is attached and reject frame 225 on which no semiconductor chip has been attached. The camera 299 and the alignment apparatus are used for recognizing and aligning the PCB 200 and the semiconductor chip. A memory device and a pattern recognition process are additionally associated with the camera 299 so that the pattern(s) observed by the camera may be compared with pattern information provided in a memory for recognizing the specific pattern formed on the surface of the semiconductor chip 207 and may be used further upon recognition and alignment of the semiconductor chip 207.

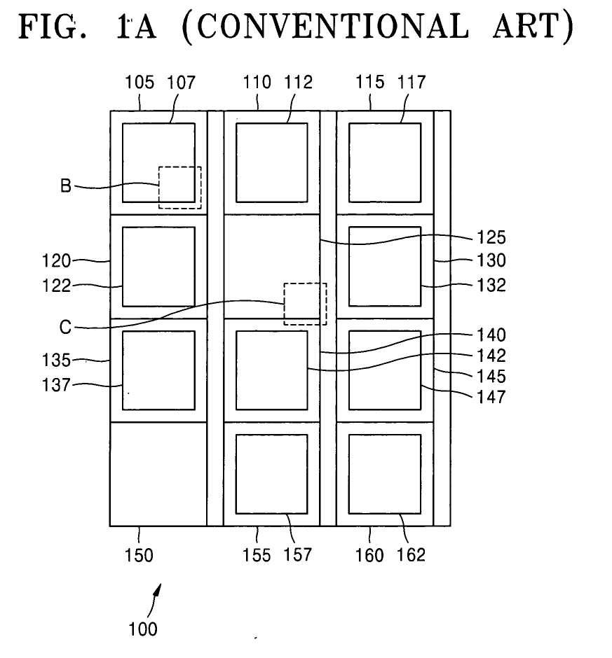

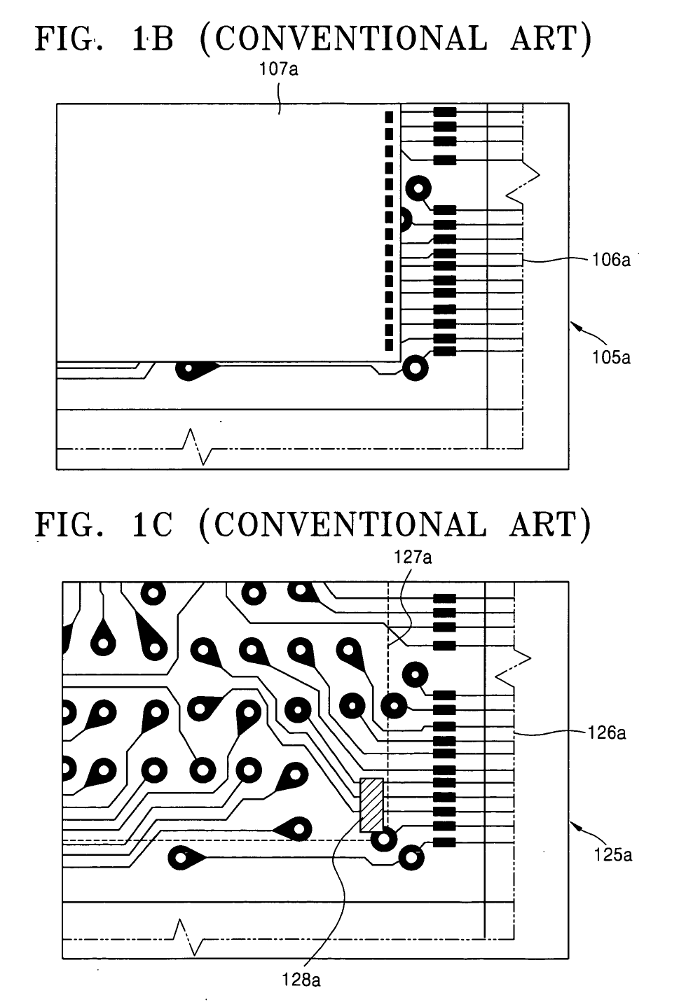

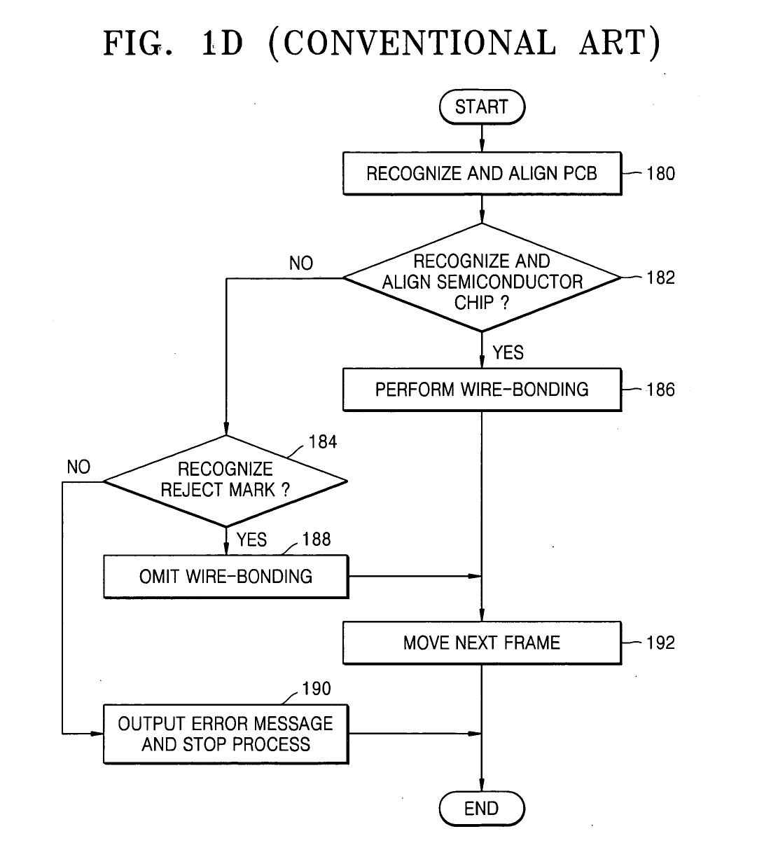

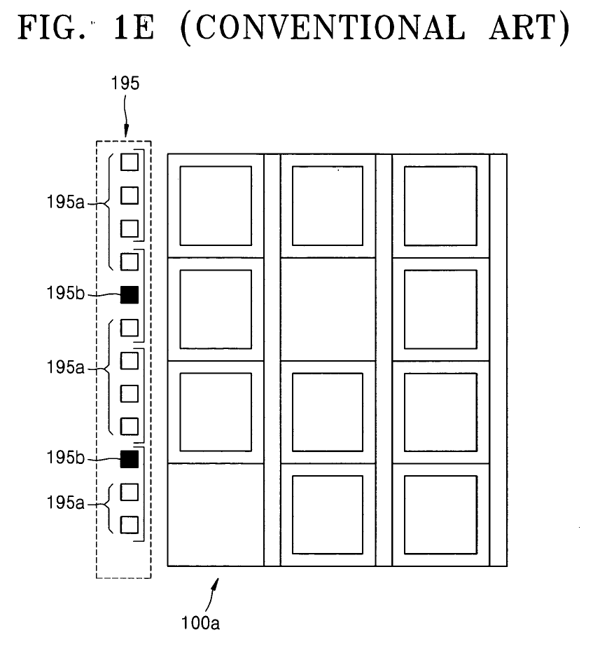

A z-axis sensor 250 configured for vertical movement from a location above the frames 290 and 292 is provided for determining whether the analyzed frames include a reject frame. In some cases, it may be necessary to operate the z-axis sensor 250 only when the camera 299 fails to recognize the semiconductor chip, thereby reducing the process time by omitting unnecessary z-axis sensor movement. The z-axis sensor 250 is connected to az-axis sensor motor (not shown) so that its movement is controlled by the z-axis sensor controller represented by a reference numeral 260 of FIG. 1A. The z-axis sensor 250 includes a device (not shown) capable of detecting a load change or a pulse current applied for detecting contact between the z-axis sensor and the reject frame 225 or the semiconductor chip 207.

As illustrated in FIGS. 2A and 2D, the z-axis sensor controller 260 measures the distance Zp between a reference position 297 and a touch point of the semiconductor chip 207 on the package frame 205, and a distance Zr between a reference position 297 and a touch point of the reject frame 225, by lowering the z-axis sensor 250 down toward the upper surface of frames 205 and 225 from the reference position 297. Zp and Zr are referred to herein as “z-levels.” The z-axis sensor controller 260 detects a load change or a change in a pulse current applied to the z-axis sensor and compares it with a sensitivity in order to recognize the point at which the z-axis sensor touches a surface.

More careful examination of the operation for recognizing the touching the upper surface of the frame by the z-axis sensor 250 by the z-axis sensor controller 260 shows that the z-axis sensor 250 accelerates and decelerates during its initial descent toward the frame. The descent may be made utilizing a mode for controlling the position of the z-axis sensor 250 before the distance range in which a touch is anticipated. Subsequently, the motion of the z-axis sensor 250 may be switched to utilize a constant descent speed until a touch is detected and may be achieved by controlling a current. If the z-axis sensor 250 is a capillary-type probe, it is suggested that the z-axis sensor be configured to descend in a manner whereby the contact force will be no more than about 20 to 30 grams force when contacting the upper surface of the frame. Contact forces in this range will generally be sufficient to avoid making a capillary mark on the semiconductor chip, but even lower contact forces may suffice depending on the apparatus. Subsequently, a touch detecting algorithm is activated during the constant descent speed motion of the z-axis sensor 250 for detecting force, a pulse-current count and sensitivity. As used herein, the term force refers to the maximum possible force applied to the frame by the z-axis sensor 250. The pulse-current count is the number of samplings of a pulse current change read to recognize the touch during the constant motion of the z-axis sensor 250 and the touch is recognized by comparing the number of samplings for the pulse current with a sensitivity.

The host controller 270 may identify or determine reject frames by comparing the distance between the reference position 297 and a critical position 295, i.e., the reference level Zs, with the z-level. If a z-level Zr is greater than the reference level Zs (Zr>Zs), the frame 225 is determined to be a reject frame, and if a z-level Zp is not greater than the reference frame Zs (Zp≦Zs), the frame is determined to be a good frame or a package frame. The reference level may have an inverse proportional relationship to the thickness of the semiconductor chip or stack of semiconductor chips attached on the frame. Generally, the reference level is set to an average value capable of reducing error after accumulating distance data over many experiments focusing on a specific semiconductor chip. In some cases, the reference level may be set to an intermediate value between the z-level of the package frame and the z-level of the reject frame or adjusted in light of the value previously measured on a neighboring frame.

The apparatus for wire bonding and die attaching includes an apparatus for general wire bonding (not shown) and an apparatus for die attaching (not shown), in addition to the system for determining reject frames using the z-level, the basic structure and operation of these components will be well known to those skilled in the art and will not, therefore, be discussed at length herein. Therefore, the system according to the exemplary embodiments of the invention for determining reject frames can be integrated with and cooperate with the bonding apparatus and die attaching apparatus. In this manner, if the frame of the PCB is determined to be a package frame, the wire boding and the die attaching operations are performed, and if the frame of the PCB is determined to be a reject frame, the wire bonding and the die attaching operations are automatically omitted, thereby reducing the downtime of the apparatus.

The exemplary apparatus for wire bonding and die attaching can efficiently identify reject frames by measuring the z-level of the respective frame using the z-axis sensor and comparing it with the reference level, without requiring a reject mark or a reject frame map on the frame of the PCB, on which one or more stack-type semiconductor chips are attached. Therefore, the exemplary apparatus for wire bonding and die attaching can determine reject frames with a reduced error rate when compared with the conventional systems that rely on recognition of the reject mark or the conventional determination of the reject frame through recognition of the reject frame map where the reject mark is falsely marked or recognized. Further, if recognition of the semiconductor chip by the camera and recognition of the reject frame through measurement of the z-level are performed together, the error rate can be reduced even further. Also, as the rate of automatically omitting the operations of bonding the wire and attaching the die of reject frames is increased, the downtime associated with errors in the reject mark or the reject frame map or an error in recognition of the apparatus may be correspondingly reduced.

### Second Exemplary Embodiment

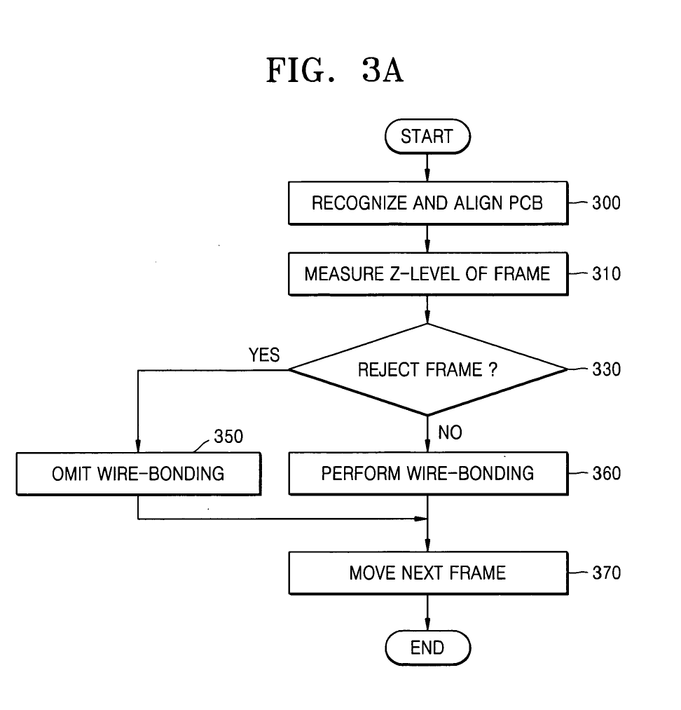

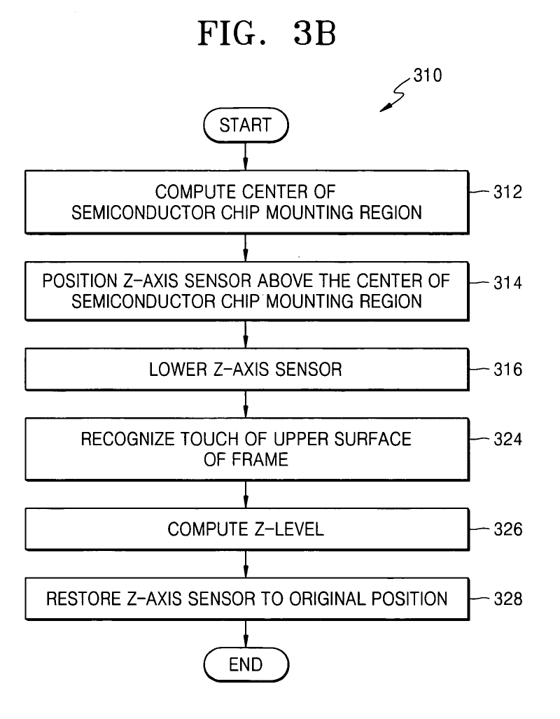

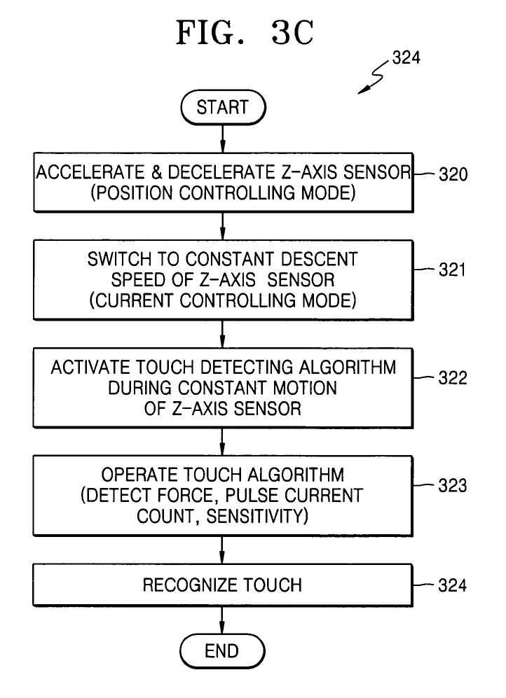

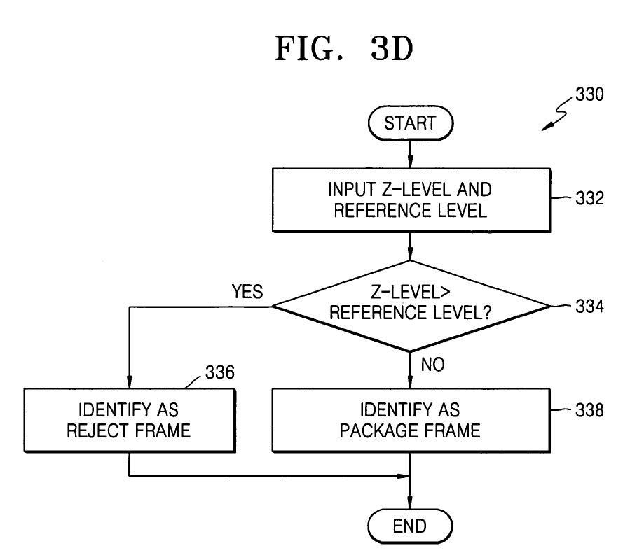

FIGS. 3A through 3D are flowcharts explaining the method for bonding the wire according to another exemplary embodiment of the present invention. Since the method for bonding the wire according to this embodiment of the present invention uses the apparatus for bonding the wire according to the first exemplary embodiment, the structure thereof will be easily understood by those skilled in the art through the explanation provided above in connection with the first exemplary embodiment.

As illustrated in FIG. 3A, the method for bonding the wire according to an exemplary embodiment of the present invention first recognizes and aligns a PCB having a plurality of package frames on which one or more stack-type semiconductor chips are attached and a plurality of reject frames on which no semiconductor chips are attached 300. The operation of recognizing and aligning the PCB 300 can be performed using the camera and the alignment apparatus having a memory function, as described in connection with the first exemplary embodiment.

Subsequently, the z-level of one frame of the PCB is measured 310. As described in the first exemplary embodiment, operation 310 may include measuring the z-level by reading a pulse current change and comparing it with a sensitivity to recognize the point where the z-axis sensor touches the upper surface of the frame being probed. Next, whether the frame is a reject frame is determined by comparing the measured z-level with the reference level 330. The operation 330 for determining the reject frame may identify the frame being probed as a reject frame if the detected z-level is greater than the reference level corresponding to the semiconductor chip that is expected to be attached to the frame. Also, as in the previous embodiment, the reference level may have an inverse proportional relationship to the thickness of the semiconductor chip or stack of semiconductor chips attached on the frames. If the frame is determined to be a reject frame, the operation of wire bonding is then omitted for the frame 350 and, if the frame is determined to be a non-reject frame, the operation of wire bonding is performed on the frame 360.

After the operation 350 for omitting the wire-bonding for the reject frame or the operation 360 for performing the wire-bonding for the package frame, the process is performed on the next frame 370 by repeating the series of operations detailed above on the next frame.

As illustrated in FIG. 3B, the operation 310 for measuring the z-level will be described in detail. First, the center of a semiconductor-chip-mounting region on the frame is computed 312. The computation can be performed in such a way that the center of the semiconductor-chip-mounting region is the intersection of two diagonals. Subsequently, the z-axis sensor will typically be positioned at a location generally above the center of the semiconductor-chip-mounting region 314. The z-axis sensor is then lowered 316 toward the frame until contact between the z-axis sensor and the upper surface of the frame is recognized 324. Once the touch or contact has been recognized, the z-level distance between the touch and the reference position is computed 326. After the z-level has been or is being computed, the z-axis sensor may be returned to its original position 328.

As illustrated in FIG. 3C, the operation 324 for recognizing the touch will be described in detail. The z-axis sensor accelerates and decelerates the rate of its descent 320 according to its position above the frame. When the z-axis sensor is within a range of the anticipated surface of the frame, the motion of the z-axis sensor may be switched to a constant descent speed 321 and a touch detecting algorithm is activated 323 for detecting force, pulse-current count and sensitivity until a touch is detected. The touch is recognized by comparing the number of samplings for the pulse current with a sensitivity 324.

As illustrated in FIG. 3D, the operation 330 for determining reject frames will be described in detail. First, the z-level measured for one frame and the reference level set in advance are input 332. The reference level is set depending on the particular semiconductor chip attached to the frames and may have an inverse proportional relationship to the thickness of the semiconductor chip or stack of semiconductor chips that is expected to be found attached to the frames.

Subsequently, the measured z-level is compared with the reference level 334. If the z-level is greater than the reference level, the frame is determined to be a reject frame 336 and, if the z-level is less than or equal to the reference level, the frame is determined to be a package frame 338.

The method for wire bonding according to this embodiment of the present invention does not use the reject mark or the reject frame map which have been used in conventional methods, but instead, identifies reject frames dynamically using the z-level before initiating a wire bonding operation. Therefore, reject frames can be efficiently identified without regard for errors in applying or identifying the reject mark or the reject frame map during the packaging process for single or stack-type semiconductor chip products. Also, because the rate of automatically omitting the wire-bonding of reject frames can be increased, it is possible to reduce the downtime of the apparatus associated with errors occurring during the conventional process error in the identification or determination of reject frames.

### Third Exemplary Embodiment

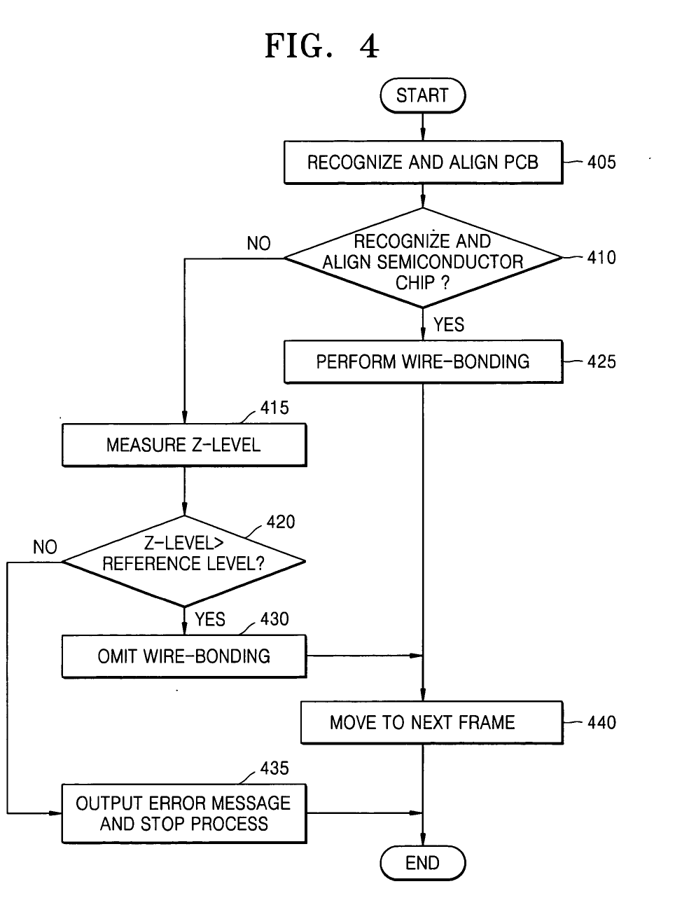

FIG. 4 is a flowchart showing a method for wire bonding according to another exemplary embodiment of the present invention. Because the method for bonding the wire according to this exemplary embodiment of the present invention utilizes the apparatus for bonding the wire according to the first embodiment detailed above, it is believed that the structure and operation of the apparatus will be easily understood by those skilled in the art with reference to the explanation of the first embodiment.

As illustrated in FIG. 4, the method for bonding the wire according to this embodiment of the present invention first recognizes and aligns the PCB 405. Subsequently, a semiconductor chip on the frame is recognized and aligned 410. The recognition of the semiconductor chip may be performed by the camera having the memory function and the alignment apparatus as described in the first embodiment.

As illustrated in FIG. 4, the method for bonding the wire according to this embodiment of the present invention first recognizes and aligns the PCB 405. Subsequently, a semiconductor chip on the frame is recognized and aligned 410. The recognition of the Semiconductor chip may be performed by the camera having the memory function and the alignment apparatus as described in the first embodiment.

In that case, if the semiconductor chip is recognized and aligned, the operation of wire bonding is subsequently performed 425. However, if the semiconductor is not recognized and aligned, the z-level is then measured for the frame to discriminate whether the frame is a reject frame 415. The operation for measuring the z-level can be performed as described above in connection with the second exemplary embodiment. Following the operation 415 for measuring the z-level, the measured z-level is compared with the reference level 420. The reference level may be determined in advance depending on the particular semiconductor chip and PCB, and may have an inverse proportional relationship to the thickness of the semiconductor chip or stack of semiconductor chips that will be attached to the frames when properly manufactured.

If the z-level is greater than the reference level, the frame is determined to be a reject frame and the operation of wire bonding is omitted 430. Otherwise, an error message is output and the process is stopped 435. If the process is stopped, an operator checks, in person, whether the semiconductor chip is attached or not. If the operator finds a semiconductor chip is properly attached, the operation of recognizing and aligning the semiconductor chip is performed again. If the semiconductor chip is not recognized even in that case, a recognition and alignment program is modified and performed again. After the operation of wire bonding is performed 425 or the operation of wire bonding is deliberately omitted 430, the process advances to the next frame and the process steps outlined are repeated.

The method for wire bonding according to this embodiment of the present invention performs the operation of wire bonding for those frames on which no error is detected, through recognition and alignment of the semiconductor chip, and measures the z-level only for the frame where an initial recognition error is detected, to provide a second means for identifying reject frames, thereby eliminating the need to measure the z-level for all the frames. Namely, by combining the technology for recognizing the semiconductor chip using the camera with the technology for determining reject frames through measurement of the z-level, reject frames can be discriminated with a more lower error rate in one or more stack-type semiconductor chips. Also, it is possible to reduce the downtime of the apparatus and device failures associated with errors in identifying reject frames, thereby raising the rate at which the operation of wire bonding is omitted for reject frames.

The apparatus and method for bonding the wire according to exemplary embodiments of the present invention can dynamically discriminate reject frames by measuring the z-level using the z-axis sensor even without a separate reject mark or reject frame map with respect to the PCB having a plurality of package frames and reject frames.

According to exemplary embodiments of the present invention, therefore, it is possible to identify reject frames by changing the reference level not only with respect to the stack-type package frame where a plurality of semiconductor chips are stacked, but also as to those package frames where a single semiconductor chip is attached, and therefore, improved integration of the package manufacturing process can be achieved.

Also, according to exemplary embodiments of the present invention, errors in discrimination of reject frames due to the conventional error in the reject mark or the reject frame map can be effectively reduced by using the z-level, and accordingly, the rate at which the operation of wire bonding is automatically omitted for reject frames can be raised, reducing downtime of the apparatus and/or failure processing time of the operator.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An apparatus for performing packaging operations on a PCB including a plurality of frames, comprising:
a z-axis sensor, the z-axis sensor being configured for movement generally normal to an upper surface of a frame;
an alignment device for sequentially positioning frames relative to the z-axis sensor;
a z-axis sensor controller for controlling movement of the z-axis sensor in a direction generally normal to the upper surface and for sensing contact between the z-axis sensor the upper surface of the frame; and
a host controller arranged and configured for utilizing the sensed contact for determining if the frame is a reject frame.

2. An apparatus for performing packaging operations on a PCB including a plurality of frames according to claim 1, wherein:
the z-axis sensor controller is configured for limiting a contact force generated between the z-axis sensor and the upper surface of the frame to no more than about 30 grams force.

3. An apparatus for performing packaging operations on a PCB including a plurality of frames according to claim 1, wherein:
the z-axis sensor controller provides for movement between an initial position and an intermediate position at a first rate of advance and movement between the intermediate position and a final position at a point where contact with the upper surface of the frame is expected at second rate of advance, the second rate of advance being less than the first rate of advance.

4. An apparatus for performing packaging operations on a PCB including a plurality of frames according to claim 3, wherein:
the second rate is substantially constant.

5. An apparatus for performing packaging operations on a PCB including a plurality of frames according to claim 1, wherein:
the z-axis sensor controller is configured for recognizing a change of sufficient magnitude in a pulse current applied to the z-axis sensor to detect contact with the upper surface of the frame.

6. An apparatus for performing packaging operations on a PCB including a plurality of frames according to claim 1, wherein:
the z-axis sensor controller is configured for recognizing a change in a load applied to the z-axis sensor to detect contact with the upper surface of the frame.

7. An apparatus for performing packaging operations on a PCB including a plurality of frames according to claim 1, wherein:
the alignment device includes a camera for recognizing and aligning the frame relative to the z-axis sensor.

8. An apparatus for performing packaging operations on a PCB including a plurality of frames according to claim 1, wherein:
the host controller is arranged and configured for comparing the detected position with a reference position to determine if the frame is a reject frame.

9. An apparatus for performing packaging operations on a PCB including a plurality of frames according to claim 1, wherein:
the reference position accounts for one or more semiconductor chips attached to the frame.

10. An apparatus for performing packaging operations on a PCB including a plurality of frames according to claim 1, wherein:
the host controller is arranged and configured for terminating movement of the z-axis sensor when a traveled distance exceeds the reference position by a set amount when no contact with the upper surface of the frame has been detected.

11. A method for performing device packaging operations on a PCB including a plurality of frames comprising:
positioning the z-axis sensor above a first frame on the PCB;
recognizing and aligning the first frame on the PCB relative to a z-axis sensor;
measuring a z-level distance between a reference position and the upper surface of the first frame with the z-axis sensor;
comparing the measured z-level distance Zp with a reference level Zs;
terminating processing of the first frame when Zp>Zs or performing at least one additional process on the first frame when Zp≦Zs; and
repositioning the z-axis sensor above to a second frame on the PCB.

12. A method for performing device packaging operations on a PCB including a plurality of frames according to claim 11, wherein:
the at least one additional process includes wire bonding or die attaching.

13. A method for performing device packaging operations on a PCB including a plurality of frames according to claim 11, wherein:
the reference level Zs is adjusted to account for the z-level Zp measured for at least one previously measured frame that received at least one additional process.

14. A method for performing device packaging operations on a PCB including a plurality of frames according to claim 11, wherein:
the reference level Zs is adjusted to reflect an anticipated presence of at least one previously mounted semiconductor chip.

15. A method for performing device packaging operations on a PCB including a plurality of frames according to claim 11, wherein:
measuring the z-level distance includes at least one of detecting a change in a pulse current applied to the z-axis sensor or detecting a change in a load applied to the z-axis sensor.

16. A method for performing device packaging operations on a PCB including a plurality of frames:
examining a designated frame for the presence of an expected semiconductor chip mounted on the frame and
if the expected semiconductor chip is detected,
performing additional processing on the semiconductor chip and
if the expected semiconductor chip is not detected,
measuring a z-level distance between a reference position and the upper surface of the designated frame and
comparing the measured z-level distance Zp with a reference distance Zs and,
if Zp>Zs, terminating processing of the designated frame and advancing to a next designated frame.

17. A method for performing device packaging operations on a PCB including a plurality of frames according to claim 16, wherein:
if Zp≦Zs, reexamining the designated frame for the presence of the expected semiconductor chip and, if detected, performing additional processing on the semiconductor chip.

18. A method for performing device packaging operations on a PCB including a plurality of frames according to claim 16, wherein:
the additional processing includes at least one of die attaching and wire bonding.

19. A method for performing device packaging operations on a PCB including a plurality of frames according to claim 16, wherein:
examining the designated frame for the presence of the expected semiconductor chip mounted on the frame includes
aligning the frame;
imaging the frame to obtain an observed pattern image;
comparing the observed pattern image with a stored pattern image; and
indicating a match when the observed pattern image and the stored pattern image are sufficiently similar.

20. A method for performing device packaging operations on a PCB including a plurality of frames according to claim 16, wherein:
measuring a z-level distance between a reference position and the upper surface of the designated frame includes
aligning the designated frame relative to a z-axis sensor;
advancing the z-axis sensor toward the designated frame from a reference position until a position reached where contact between the z-axis sensor and the upper surface is detected; and
returning the z-axis sensor to the reference position.
